(19) United States
(12) Patent Application Publication
(10) Pub. No.: US 2010/0117082 A1
(43) Pub. Date: May 13, 2010

(54) SEMICONDUCTOR DEVICE CAPABLE OF COMPENSATING FOR ELECTRICAL CHARACTERISTIC VARIATION OF TRANSISTOR ARRAY

(76) Inventors: DAE WOOK KIM, Hwasung-si (KR); Ji-Seong Doh, Hwasung-si (KR); Sang Hoon Lee, Seongnam-si (KR); Ji Suk Hong, Hwasung-si (KR)

Correspondence Address: F. CHAU & ASSOCIATES, LLC, 130 WOODBURY ROAD, WOODBURY, NY, 11797, US

(21) Appl. No.: 12/617,082

(22) Filed: Nov. 12, 2009

(30) Foreign Application Priority Data
Nov. 12, 2008 (KR) 10-2008-0112367

(51) Int. Cl. H01L 27/085

(52) U.S. Cl. 257/48; 257/205; 257/E27.059

(57) ABSTRACT

A semiconductor device capable of compensating for an electrical characteristic variation of a transistor array is provided. The semiconductor device includes an N-well region and a transistor array spaced from the N-well region and including a plurality of transistors. A characteristic of each of the transistors is adjusted to enable the transistors to have a same electrical characteristic.

### CROSS-REFERENCE TO RELATED APPLICATION

This application claims under 35 U.S.C. §119 priority to and the benefit of Korean Patent Application No. 10-2008-0112367 filed on Nov. 12, 2008, in the Korean Intellectual Property Office, the entire content of which is incorporated by reference herein.

### BACKGROUND

1. Technical Field

The present inventive concept relates to semiconductor devices, and more particularly, to semiconductor devices capable of compensating for a variation in an electrical characteristic according to a position of a transistor.

2. Discussion of Related Art

In a semiconductor device, such as an image sensor, a display driver, or a memory device, including a plurality of transistor pairs or a transistor array, the transistors need to have the same electrical characteristics (e.g., a source-drain current characteristic or a threshold voltage characteristic) to prevent the semiconductor device from malfunctioning. However, the transistors may have different electrical characteristics according to their positions in a substrate.

For instance, the electrical characteristics of a transistor may be varied by well proximity effects (WPE). For example, WPE can occur during a CMOS manufacturing process where atoms scatter laterally from an edge of a photoresist mask and become embedded in a silicon surface near edges of wells needed for latch-up protection and suppression of lateral punch-through. Such a structure can cause MOSFET electrical characteristics to vary with the distance of the transistor from the well-edge.

Also, the electrical characteristics of a transistor may be varied by shallow trench isolation (STI). For example, STI effects can occur because during a semiconductor device fabrication process, before transistors are formed a pattern of trenches may be etched in the silicon, with one or more dielectric materials filling the trenches and providing an STI region which may affect electrical current leakage between adjacent semiconductor device components.

### SUMMARY

An exemplary embodiment of the present inventive concept provides a semiconductor device capable of compensating for an electrical characteristic variation.

According to an exemplary embodiment of the present inventive concept a semiconductor device includes: a well region, and a transistor array spaced from the well region. The transistor array includes a plurality of substantially similar transistors, at least one transistor more distal from the well region having an adjusted structure as compared to a transistor more proximal to the well region such that the plurality of the substantially similar transistors have substantially the same electrical characteristics.

The adjusted structure may include at least one amongst: a gate width adjustment, a gate length adjustment, a contact size adjustment, the number of contacts adjustment, a distance adjustment between a gate and a contact, a metal length adjustment, a metal width adjustment, and a diffusion length adjustment.

The electrical characteristics may be at least one amongst: current flowing between a gate and a drain of each transistor, and gate threshold voltage of the transistor.

The electrical characteristics may be varied based upon at least one of well proximity effect and shallow trench isolation.

When one of the plurality of substantially similar transistors has less source-drain current than other transistors among the plurality of substantially similar transistors, a length of the transistor may be decreased or a width of the transistor may be increased.

The plurality of substantially similar transistors may include a first group transistors a first distance away from the well region and a second group transistors a second distance away from the well region, the second distance being different from the first distance.

The structure of the transistor more distal from the well region may be adjusted by analyzing the electrical characteristics of the transistor more distal from the well region and the transistor more proximal to the well region to determine whether a structural change is needed to provide a change in the electrical characteristics to the transistor more distal from the well region based upon a result of the analyzing, and upon determining that a structural change is needed, making the structural change.

The structure of the transistor more distal from the well region may be further adjusted by, upon determining that an electrical characteristic variation is not compensated for, repeat analyzing the electrical characteristics to determine whether a structural change is needed to provide a change in the electrical characteristics of the transistor more distal from the well region based upon a result of the analyzing, and upon determining that a structural change is needed, making the structural change.

According to an exemplary embodiment of the present inventive concept semiconductor device includes a first transistor and a second transistor. A structure of the first transistor is adjusted differently from a structure of the second transistor such that the first transistor and the second transistor have substantially the same electrical characteristics in view of the first transistor and the second transistor being affected by at least one of a well proximity effect and a shallow trench isolation effect.

The structure of the first transistor and the structure of the second transistor may be adjusted based upon distance between a neighboring well and a corresponding transistor.

The structure of the first transistor and the structure of the second transistor are adjusted based upon number of adjacent transistors and distances from the adjacent transistors.

The structure of the first transistor and the structure of the second transistor are adjusted by analyzing the electrical characteristics of the first transistor and the second transistor to determine whether a structural change is needed to provide a change in the electrical characteristics among the first transistor and the second transistor based upon a result of the analyzing, and upon determining that a structural change is needed, making the structural change.

The structure of the first transistor and the second transistor may be further adjusted by, upon determining that an electrical characteristic variation is not compensated for, repeat analyzing the electrical characteristics of the first transistor and the second transistor to determine whether a structural change is needed to provide a change in the electrical characteristics among the first transistor and the second transistor based upon a result of the analyzing, and upon determining that a structural change is needed, making the structural change.

According to an exemplary embodiment of the present inventive concept semiconductor device includes a plurality of transistors in a row. Each of the transistors in the row have a plurality of contacts. At least one transistor at end of the row has more contacts than the other transistors in the row.

### BRIEF DESCRIPTION OF THE DRAWINGS

The above and other features and advantages of the present inventive concept will become more apparent by describing in detail exemplary embodiments thereof with reference to the attached drawings in which:

FIG. 1 is a plan view of a semiconductor device according to an exemplary embodiment of the present inventive concept;

FIG. 2 illustrates transistors in a transistor array illustrated in FIG. 1 according to an exemplary embodiment of the present inventive concept;

FIG. 3 illustrates transistors in the transistor array illustrated in FIG. 1 according to an exemplary embodiment of the present inventive concept; and

FIG. 4 is a flowchart of a method of compensating for an electrical characteristic variation of a transistor array according to an exemplary embodiment of the present inventive concept.

### DETAILED DESCRIPTION OF THE EMBODIMENTS

The present inventive concept now will be described more fully hereinafter with reference to the accompanying drawings, in which embodiments of the invention are shown. This inventive concept may, however, be embodied in many different forms and should not be construed as limited to the embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present.

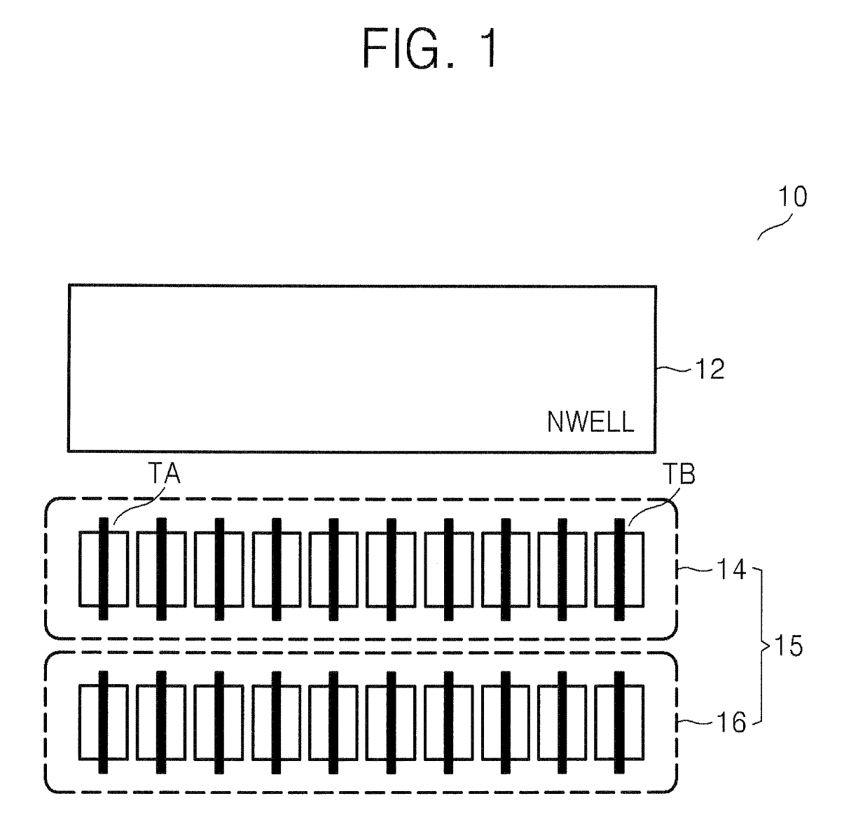

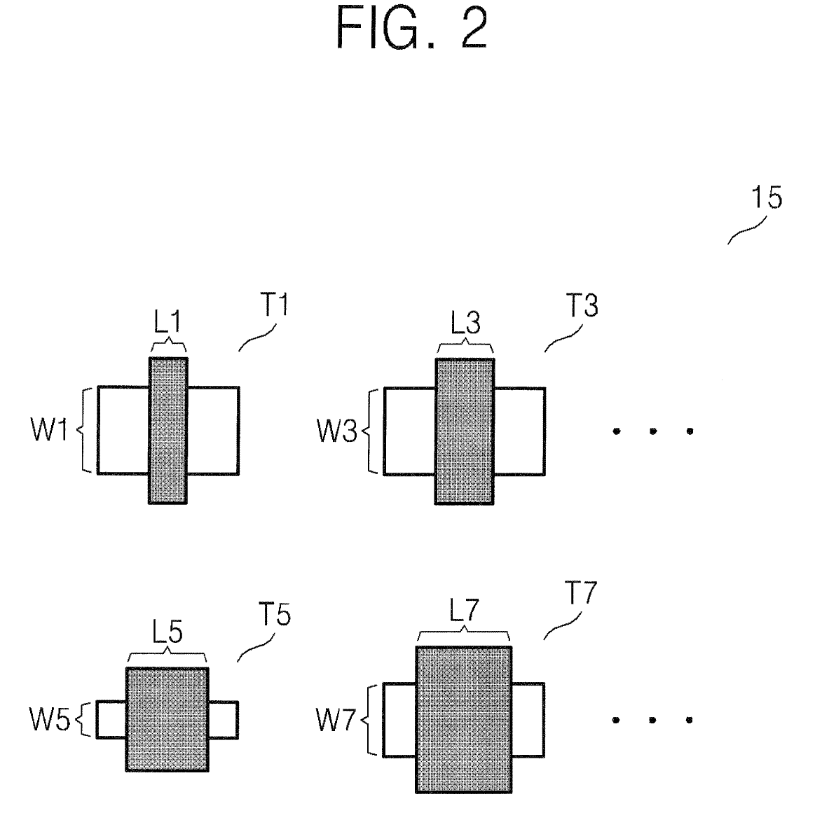

FIG. 1 is a plan view of a semiconductor device 10 according to an exemplary embodiment of the present inventive concept. FIG. 2 illustrates transistors in the transistor array 15 illustrated in FIG. 1. Referring to FIGS. 1 and 2, the semiconductor device 10, which may be implemented in an image sensor, a display driver, or a memory device, includes an N-well region 12 and the transistor array 15. The N-well region 12 is formed in a P-type substrate by implanting N-type impurities into the P-type substrate. The N-well region 12 may be formed above a deep N-well region. Although it is not illustrated in FIG. 1, P-type (PMOS) transistors may be formed in the N-well region 12.

The transistor array 15 is spaced from the N-well region 12 and includes a plurality of transistors (e.g., transistors T1, T3, T5, T7). The plurality of transistors T1, T3, T5, T7 may be N-type (NMOS) transistors. The transistors T1, T3, T5, T7 may be cells that store data. The electrical characteristics of each of the transistors T1, T3, T5, T7 included in the transistor array 15 may be varied by WPE or STI. The affected electrical characteristics may include at least one from amongst: current flowing between a gate and a drain of a transistor, and gate threshold voltage of the transistor.

For instance, when transistors in a first group 14 (hereinafter, referred to as first group transistors) are a first distance away from the N-well region 12 and transistors in a second group 16 (hereinafter, referred to as second group transistors) are a second distance away from the N-well region 12, the second distance being greater than the first distance, are implemented by devices having substantially the same structure, the electrical characteristics of the first group transistors may be different from the electrical characteristics of the second group transistors due to the different distances away from the N-well region 12, resulting in WPE. In addition, although each of the first group transistors have substantially the same structure, transistors TA, TB located at both ends of the first group 14 may have a different electrical characteristics than the other transistors in the first group 14 since the transistors TA, TB each has only one adjacent transistor, resulting in an STI effect. The impact of the WPE and/or STI effect on a transistor may be different depending on a type of the transistor or fabrication processes thereof. As for the WPE, the distance from a well predominately affects the characteristics of a transistor. As for the STI effect, the numbers of adjacent transistors and the distances from the adjacent transistors affect the characteristics of a transistor. Of course, the WPE and STI effect can be cumulative for transistors in locations affected by both WPE and STI.

One attempt to prevent the WPE and/or the STI effect, involves a configuration such that transistors have the same surroundings using a dummy transistor or a chip may be designed large. Even in this case, however, it is still difficult to maintain the characteristics of all transistors the same and an increase in a chip size may incur an increase in manufacturing cost.

According to an exemplary embodiment of the present inventive concept, one or more of the exemplary transistors T1, T3, T5, T7 may be adjusted such that all of the transistors T1, T3, T5, T7 have the same electrical characteristic. Here, the adjustment may be at least one amongst: gate width (i.e., a width of a gate), gate length (i.e., a length of the gate), contact size, the number of contacts, distance between the gate and a contact, metal length (i.e., a length of a metal), a metal width (i.e., a width of the metal), and diffusion length of a transistor.

For instance, when a transistor T5, among the transistors T1, T3, T5, T7 has less source-drain current than the other transistors T1, T3, T7, a length W5 of the transistor T5 may be decreased or a width L5 thereof may be increased. On the other hand, when transistor T5 has greater source-drain current than the other transistors T1, T3, T7, the length W5 of the transistor T5 may be increased or the width L5 thereof may be decreased. Similar adjustments can also be made to dimensions L1, W1 of transistor T1, to dimensions L3, W3 of transistor T3 and to dimensions L7, W7 of transistor T7 as needed to fine tune their electrical characteristics.

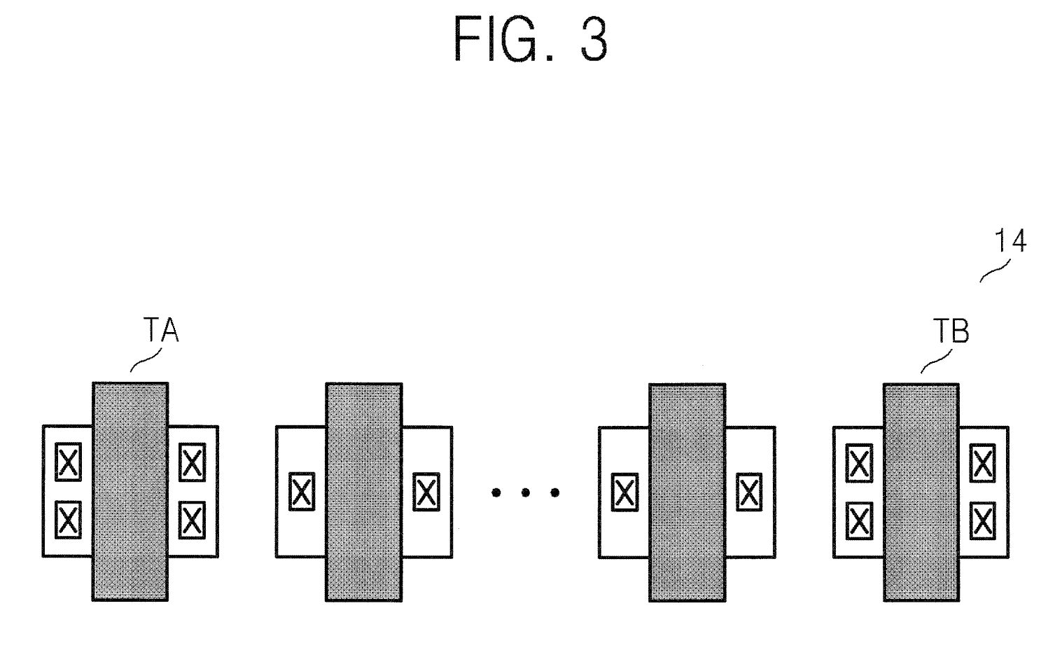

FIG. 3 illustrates transistors in the transistor array 15 illustrated in FIG. 1 according to an exemplary embodiment of the present inventive concept. Referring to FIGS. 1 and 3, the transistors TA, TB at both ends of the first group 14, may have more contacts than the other transistors of the first group 14 such that the transistors TA, TB have the same electrical characteristics as the other transistors in the first group 14, thereby preventing the STI effect. In addition, when the transistors TA, TB allow greater current to flow than the other transistors in the first group 14, the contact size of the transistors TA, TB may be reduced to match the current flow electrical characteristic with that of the other transistors in first group 14.

A semiconductor device according to an exemplary embodiment of the present inventive concept may include a transistor array and a neighboring P-well region. In such an exemplary embodiment, N-type (NMOS) transistors may be formed in the P-well region. The transistor array is spaced from the P-well region and includes a first transistor and a second transistor. The structure of the first transistor would be adjusted differently from that for the second transistor to enable the first and second transistors to have the same electrical characteristics, in view of at least one of a WPE and an STI effect. For example, the structure for the first and second transistors is adjusted according to the distance between a neighboring well and a corresponding transistor.

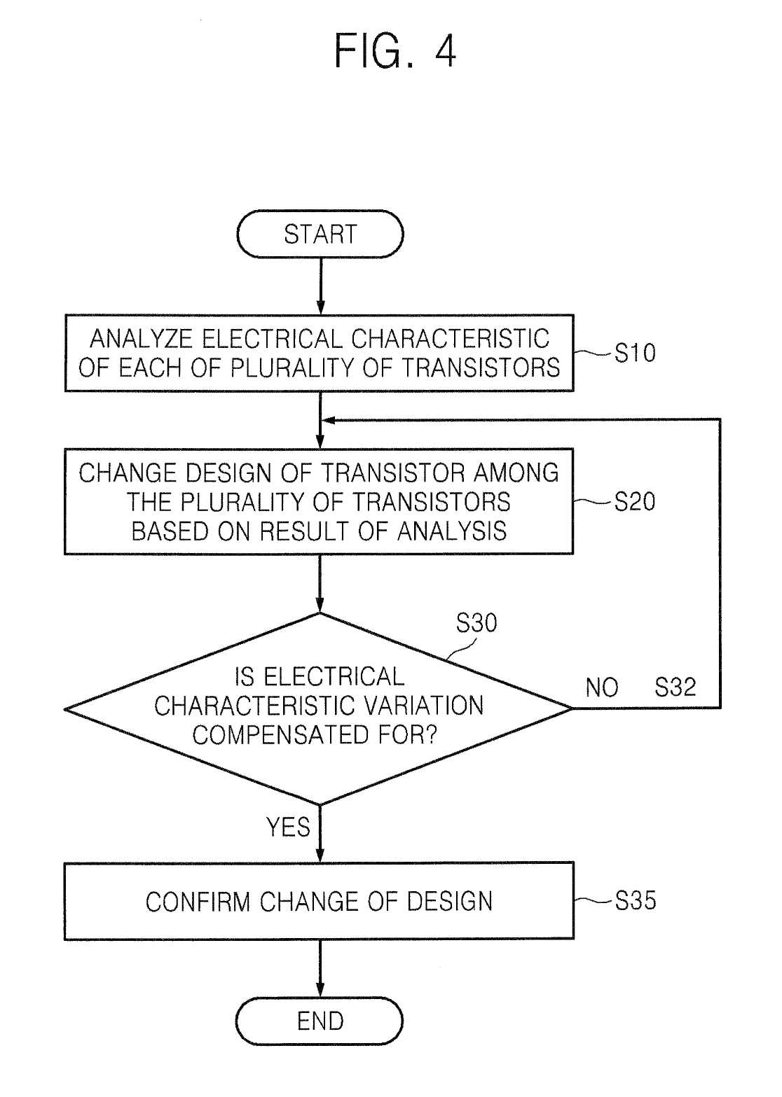

FIG. 4 is a flowchart of a method of compensating for electrical characteristics variations of a transistor array according to an exemplary embodiment of the present inventive concept. Referring to FIGS. 1, 2, and 4, a testing apparatus or simulation apparatus (not shown) analyzes the electrical characteristics of each of the transistors T1, T3, T5, T7 included in the transistor array 15 in operation S10. The operation S10 may be performed using simulation tool or by testing DUT (device under test). The DUT may be a semiconductor device manufactured or selected for testing.

In operation S20, a design of a transistor (e.g., a transistor determined to need a structural change to provide a change in the electrical characteristic) among the transistors T1, T3, T5, T7 may be changed based upon a result of the analysis of the operation S10. Here, the design may be at least one amongst: gate width, gate length, contact size, number of contacts, distance between a gate and a contact, metal length, metal width, and diffusion length of a transistor. The testing apparatus may analyze a surrounding layout and predict an electrical characteristic variation through simulation or measure the electrical characteristic variation in a chip made for a test.

The testing apparatus determines whether the transistor having a changed design has the same electrical characteristics as the other transistors, that is, whether the electrical characteristic variation of the transistor having the changed design is compensated for, after the changed design is applied in operation S30. When it is determined that an electrical characteristic variation is not compensated for, the testing apparatus repeats operation S20 in conclusionary step S32. When it is determined that the electrical characteristic variation is compensated for, the testing apparatus confirms the change of design in conclusionary step S35.

According to an exemplary embodiment of the present inventive concept, an electrical characteristic variation of a transistor array is compensated for in a semiconductor device.

While the present inventive concept has been particularly shown and described with reference to exemplary embodiments thereof, it will be understood by those of ordinary skill in the art that various changes in forms and details may be made therein without departing from the spirit and scope of the present inventive concept as defined by the following claims.

What is claimed is:

1. A semiconductor device comprising:
a well region; and
a transistor array spaced from the well region,
wherein the transistor array comprises a plurality of substantially similar transistors, at least one transistor more distal from the well region having an adjusted structure as compared to a transistor more proximal to the well region such that the plurality of the substantially similar transistors have substantially the same electrical characteristics.

2. The semiconductor device of claim 1, wherein the adjusted structure comprises at least one amongst: a gate width adjustment, a gate length adjustment, a contact size adjustment, the number of contacts adjustment, a distance adjustment between a gate and a contact, a metal length adjustment, a metal width adjustment, and a diffusion length adjustment.

3. The semiconductor device of claim 1, wherein the electrical characteristics are at least one amongst: current flowing between a gate and a drain of each transistor, and gate threshold voltage of the transistor.

4. The semiconductor device of claim 1, wherein the electrical characteristics are varied based upon at least one of well proximity effect and shallow trench isolation.

5. The semiconductor device of claim 1, wherein when one of the plurality of substantially similar transistors has less source-drain current than other transistors among the plurality of substantially similar transistors, a length of the transistor is decreased or a width of the transistor is increased.

6. The semiconductor device of claim 1, wherein the plurality of substantially similar transistors comprise a first group transistors a first distance away from the well region and a second group transistors a second distance away from the well region, the second distance being different from the first distance.

7. The semiconductor device of claim 1, wherein the structure of the transistor more distal from the well region is adjusted by:
analyzing the electrical characteristics of the transistor more distal from the well region and the transistor more proximal to the well region to determine whether a structural change is needed to provide a change in the electrical characteristics to the transistor more distal from the well region based upon a result of the analyzing; and
upon determining that a structural change is needed, making the structural change.

8. The semiconductor device of claim 7, wherein the structure of the transistor more distal from the well region is further adjusted by:
upon determining that an electrical characteristic variation is not compensated for, repeat analyzing the electrical characteristics to determine whether a structural change is needed to provide a change in the electrical characteristics of the transistor more distal from the well region based upon a result of the analyzing; and
upon determining that a structural change is needed, making the structural change.

9. A semiconductor device comprising:
a first transistor; and
a second transistor,
wherein a structure of the first transistor is adjusted differently from a structure of the second transistor such that the first transistor and the second transistor have substantially the same electrical characteristics in view of the first transistor and the second transistor being affected by at least one of a well proximity effect and a shallow trench isolation effect.

10. The semiconductor device of claim 9, wherein the structure of the first transistor and the structure of the second transistor are adjusted based upon distance between a neighboring well and a corresponding transistor.

11. The semiconductor device of claim 9, wherein the structure of the first transistor and the structure of the second transistor are adjusted based upon number of adjacent transistors and distances from the adjacent transistors.

12. The semiconductor device of claim 9, wherein the structure of the first transistor and the structure of the second transistor are adjusted by:
analyzing the electrical characteristics of the first transistor and the second transistor to determine whether a structural change is needed to provide a change in the electrical characteristics among the first transistor and the second transistor based upon a result of the analyzing; and
upon determining that a structural change is needed, making the structural change.

13. The semiconductor device of claim 12, wherein the structure of the first transistor and the second transistor are further adjusted by:
upon determining that an electrical characteristic variation is not compensated for, repeat analyzing the electrical characteristics of the first transistor and the second transistor to determine whether a structural change is needed to provide a change in the electrical characteristics among the first transistor and the second transistor based upon a result of the analyzing; and
upon determining that a structural change is needed, making the structural change.

14. A semiconductor device, comprising:
a plurality of transistors in a row, each of the transistors in the row have a plurality of contacts,
wherein at least one transistor at end of the row has more contacts than the other transistors in the row.
